(19) United States
(12) Patent Application Publication
(10) Pub. No.: US 2002/0090841 A1
(43) Pub. Date: Jul. 11, 2002

(54) Electrical connector

(76) Inventors: Eric Gillenberg, Speyer (DE); Johan Vanbesien, Leper (BE)

Correspondence Address: Tyco Technology Resources, Suite 450, 4550 New Linden Hill Road, Wilmington, DE, 19808, US

(21) Appl. No.: 09/976,371

(22) Filed: Oct. 12, 2001

(30) Foreign Application Priority Data
Oct. 13, 2000 (DE) 100 50 779.4

(51) Int. Cl. H05K 1/00

(52) U.S. Cl. 439/65

(57) ABSTRACT

The invention describes an electrical connector having a multitude of adjacent contacts and side walls. At least part of the side walls are flexibly moveable, and the side walls are positioned so that they surround at least part of the contact element region. Because of the flexibility of the side walls, an electrical connector of this type can be connected to a second electrical connector under any circumstances and without any problems.

### FIELD OF THE INVENTION

The present invention relates to an electrical connector, and more specifically, to an electrical connector with a multitude of adjacent and/or superimposed contacts and side walls surrounding at least part of the contact element region.

### BACKGROUND OF THE INVENTION

Conventional electrical connector systems, as shown in FIG. 3, consist of a first connector 1 mounted on a first electrical printed circuit board (not shown in figure) and a second connector 2 mounted on a second electrical printed circuit board 3. The connectors in each case comprise a multitude of contact elements that come into contact with each other when the connectors are mated, enabling an electrical connection between the circuit boards.

The contacts of the first connector, or more precisely, the contact region containing the contacts, is surrounded by side walls. The side walls act as a guide to ensure that corresponding connector contacts engage during the mating of the connectors.

The second connector consists of two connector halves 2a and 2b that are mounted on opposite sides of the second circuit board. This arrangement is advantageous in that a particularly high number of contacts can be accommodated in the available space. On the other hand, problems are commonly encountered when the connectors are being mated, in particular due to tolerances of the thickness of the second circuit board. As a result, it is difficult to join the first and second connectors to establish an electrical connection between the circuit boards.

### SUMMARY OF THE INVENTION

An object of the present invention is to develop a board mounted electrical connector that can be mated with a second electrical connector under circumstances where the board thickness varies within a tolerance.

This and other objects of the present invention are achieved by providing an electrical connector that has a multitude of adjacent contacts and side walls. At least part of the side walls are flexibly moveable, and the side walls are positioned so that they surround at least part of the contact region.

Partially due to the flexible design of the side walls, electrical connectors, which are not dimensioned or arranged according to exact specifications, can be duly guided to a second electrical connector. As a result, the need to exactly adjust the measurements of the second electrical connector which is to be brought into contact with the first electrical connector, and hence also the measurements of the circuit board or of another device on which the second electrical connector is mounted, can fluctuate to a relatively large extent, without jeopardising the regulatory mating ability of the connectors.

Other advantages, and novel features will become apparent from the following detailed description of the invention when considered in conjunction with the accompanying drawings.

### BRIEF DESCRIPTION OF THE DRAWINGS

FIG. 1 is a perspective view of the electrical connector arrangement of the present invention wherein a first electrical connector and a second electrical connector mounted on a circuit board are mated;

FIG. 2 is a sectional view of the arrangement shown in FIG. 1;

FIG. 3 is a perspective view of a known conventional electrical connector arrangement wherein a first electrical connector and a second electrical connector mounted on a circuit board are mated.

### DETAILED DESCRIPTION OF THE PREFERRED EMBODIMENT

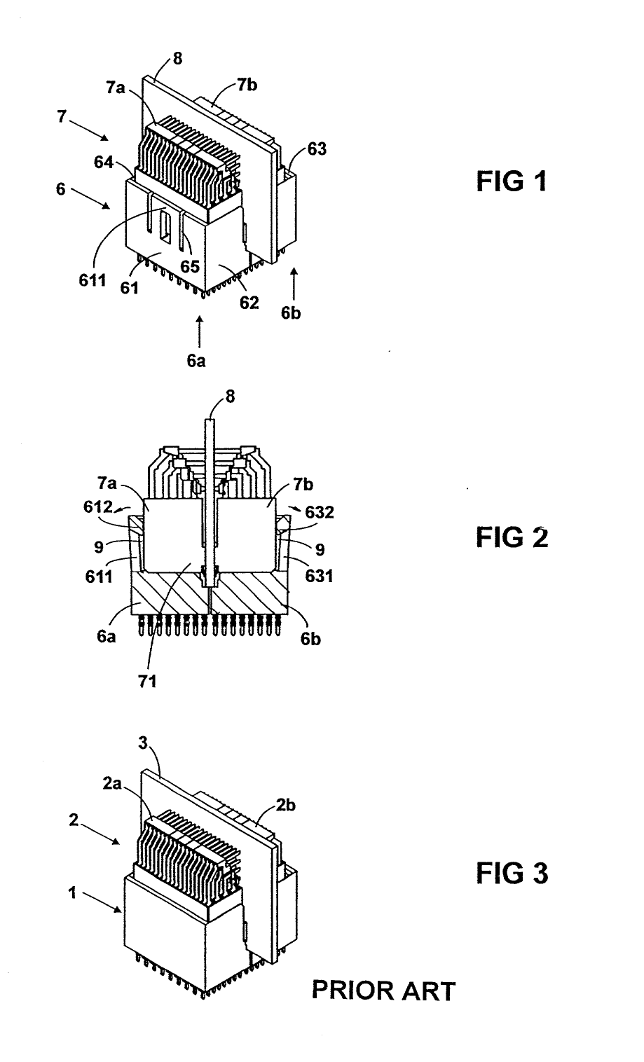

Referring to the drawings, FIG. 1 and FIG. 2 illustrate a preferred embodiment of the electrical connector of the present invention. The electrical connector has a first connector 6 mounted on a first circuit board (not shown) and a second connector 7 mounted on a second circuit board 8.

The second connector 7 consists of two identically constructed connector halves 7a and 7b. The second connector halves 7a and 7b are arranged on opposite sides of the second circuit board 8.

The first connector 6 consists of two identically constructed connector halves 6a and 6b. The first connector halves 6a and 6b are arranged opposite each other on the same side of the first circuit board (not shown).

The first or second connectors 6 or 7, however, need not consist of identically constructed connector halves. In particular, there is no need for each connector half 6a, 6b to comprise identically constructed and identically arranged contacts. It would be possible to design at least the first connector 6 as an integral unit.

The first connector 6 has a multitude of contacts (not shown). The contacts are arranged adjacent to each other in several rows or columns. The contacts of the first connector 6 consist of contact pins, but could also consist of contact sockets or other contacts, such as surface contacts.

Side walls 61, 62, 63, and 64 surround the contact region. At least parts of the side walls 61, 62, 63, and 64 are flexibly moveable. The flexibly moveable parts of the side walls 61, 62, 63, and 64 are indicated by reference numerals 611 and 631. The flexibly moveable parts 611 and 631 run parallel to the second circuit board 8. The flexibly moveable parts 611 and 631 are separated from the rest of the side walls 61 and 63 by slots 65. The flexibly moveable parts 611 and 631 have catches 612 and 632 preferably at their upper end, which extend into the region surrounded by side walls 61, 62, 63, and 64.

The side walls 61, 62, 63, and 64 of the first connector 6 and the flexibly moveable parts 611 and 631 are designed and arranged such that the front end 71 of the second connector 7 comes to lie in the region of the first connector 6 which is surrounded by the side walls 61, 62, 63, and 64 when mated with the first connector 6.

The flexible parts 611 and 631 of the side walls 61 and 63 will react differently when the connectors are mated depending on the thickness of the second circuit board 8 and the measurements of the first and second connectors 6 and 7.

In one example, a second circuit board 8 of a standard specified thickness, and first and second connectors 6 and 7 of standard specified measurements are mated between the side walls 61 or 63 running parallel to the second circuit board 8 and the second connector 7. In this case, the flexible parts 611 and 631 of the side walls 61 and 63 are pushed outwardly by the second connector 7 leaving a large intermediate space 9. No space or only a very small space is left between the side walls 62 or 64 and the second connector 7.

With maximum measurements of the first connector 6, minimal measurements of the second connector 7, and minimal thickness of the second circuit board 8, the flexible parts 611 and 631 of the side walls 61 and 63 are not pushed out as much, but still move outwardly by the second connector 7 or at least make contact.

With minimal measurements of the first connector 6, maximum measurements of the second connector 7, and with maximum thickness of the second circuit board 8, mating of the second connector 7 with the first connector 6 is still possible.

As a result, the second connector 7, irrespective of the size and size ratio of the first connector 6 and the second connector 7, and irrespective of the thickness of the second circuit board 8, is guided by the flexibly moveable parts 611 and 631 of the side walls 61 and 63, more precisely, by the catches 612 and 632 provided on the movable parts 611 and 631. In this way, the contacts of the second connector 7 are guided reliably to each allocated contact of the first connector in all circumstances.

Similarly, An electrical connector of the type described above can always be duly mated with a matching second electrical connector under any circumstances and without any problems, irrespective of the tolerance variations.

The present invention was described in detail above with reference to a preferred embodiment. This embodiment, however, is merely an example. The present invention is not limited to such an embodiment. The features of the first connector can also be used with any other electrical connectors. Also, it can be foreseen, that side walls 62 and 64, that run perpendicular to the second circuit board 8, can have flexibly moveable parts similar to the flexibly moveable parts 611 and 631. In this case, the connectors can also be brought into contact with laterally displaced connector halves 7a and 7b.

What is claimed is:

1. An electrical connector comprising:
a first electrical connector having a plurality of adjacent contacts disposed in a contact region;
a side wall having one or more parts that are flexibly moveable;
whereby the side-wall substantially surrounds the contact region.

2. The electrical connector according to claim 1, wherein the side wall has a part that is not flexibly moveable and is arranged such that when the electrical connector and a matching second electrical connector are mated, an intermediate space is left between the not flexibly moveable part of the side wall of the electrical connector and the second electrical connector.

3. The electrical connector according to claim 1, wherein, the flexibly moveable parts extend at least partly into the contact region.

4. The electrical connector according to claim 1, wherein the flexibly moveable parts are arranged such that during mating with a matching second electrical connector, the flexibly moveable parts come into contact with the second electrical connector.

5. The electrical connector according to claim 4, wherein the flexibly moveable parts are arranged such that when mated with the matching second electrical connector the flexibly moveable parts are pushed aside by the second electrical connector.

6. The electrical connector according to claim 4, wherein the flexibly moveable parts are arranged such that when mated with the matching second electrical connector the flexible moveable parts guide the second electrical connector.

7. The electrical connector according to claim 6, wherein the flexibly moveable parts guide the second electrical connector such that its contacts are guided to the corresponding contacts of the first electrical connector.

8. The electrical connector according to claim 1, wherein the electrical connector consists of a connector designed to be mounted on a circuit board and to be connected with a second connector mounted on a second circuit board.

9. The electrical connector according to claim 8, wherein the electrical connector consists of two halves, which are arranged opposite each other on the same side of the circuit board.

10. The electrical connector according to claim 9, wherein the two halves are of identical construction.

11. The electrical connector according to claim 8 wherein the second electrical connector consists of two halves, which are arranged on opposite sides of the second circuit board.

12. The electrical connector according to claim 11, wherein the two halves of the second electrical connector are identical.
